(19) United States
(12) Patent Application Publication
(10) Pub. No.: US 2026/0123014 A1
(43) Pub. Date: Apr. 30, 2026

(54) SEMICONDUCTOR DEVICE AND MANUFACTURING METHOD THEREOF

(71) Applicant: FUJI ELECTRIC CO., LTD., Kanagawa (JP)

(72) Inventors: Makoto SHIMOSAWA, Matsumoto-city (JP); Takaaki SUZAWA, Matsumoto-city (JP)

(21) Appl. No.: 19/001,310

(22) Filed: Dec. 24, 2024

Related U.S. Application Data
(63) Continuation of application No. PCT/JP2023/040763, filed on Nov. 13, 2023.

(30) Foreign Application Priority Data
Jan. 5, 2023 (JP) 2023-000758

(51) Int. Cl. H10D 64/62; H01L 21/285; H10D 12/00; H10D 12/01; H10D 62/83; H10D 62/832; H10D 64/23; H10D 84/00; H10D 84/01

(52) U.S. Cl. CPC H10D 64/62; H10D 12/035; H10D 12/038; H10D 12/481; H10D 64/232; H10D 84/0109; H10D 84/161; H10P 14/418; H10D 62/83; H10D 62/8325

(57) ABSTRACT

Provided is a semiconductor device, comprising: a semiconductor substrate; an interlayer dielectric film provided on the semiconductor substrate, having contact holes provided thereon, wherein the contact holes include a contact hole with a stepped portion on a sidewall; and a contact portion provided in the contact hole, wherein the contact portion has a barrier layer provided on the sidewall and a bottom surface of the contact hole, wherein the barrier layer has: a first region in direct contact with the stepped portion; and a second region in direct contact with the sidewall of the contact hole in a region different from the first region, wherein when a film thickness of a thickest portion of the first region is T and a film thickness of a thinnest portion of the second region is t, 0.3T≤t≤0.95T is satisfied.

The contents of the following patent application(s) are incorporated herein by reference:
NO. 2023-000758 filed in JP on Jan. 5, 2023
NO. PCT/JP2023/040763 filed in WO on Nov. 13, 2023

### BACKGROUND

### 1. Technical Field

The present invention relates to a semiconductor device and a method of manufacturing the semiconductor device.

### 2. Related Art

In Patent Document 1, a semiconductor device with a configuration wherein “the sidewall of the contact hole 14 has one step 14c provided at the interface between the HTO film 11 and the BPSG film 12, and the step 14c makes the width of the upper end side of the contact hole 14 wider than the width of the bottom surface side of the contact hole 14 in a step-like manner” is described.

### Prior Art Documents

### Patent Documents

Patent Document 1: Japanese Unexamined Patent Application Publication (Translation of PCT Application) No. 2019-093015.
Patent Document 2: Japanese Patent Application Publication No. S63-205951.
Patent Document 3: Japanese Patent Application Publication No. H5-299375.
Patent Document 4: Japanese Patent Application Publication No. H7-94448.
Patent Document 5: Japanese Patent Application Publication No. 2001-223218.
Patent Document 6: Japanese Translation of PCT International Patent Application No. 2004-515921.
Patent Document 7: Japanese translation publication of a PCT International Patent Application No. 2007-511087.
Patent Document 8: Japanese Patent Application Publication No. 2008-141050.

### BRIEF DESCRIPTION OF THE DRAWINGS

FIG. 1A illustrates an example of a top view of a semiconductor device 100.

FIG. 1B illustrates an example of a cross section a-a′ in FIG. 1A.

FIG. 2A illustrates a top view of a modified example of the semiconductor device 100.

FIG. 2B illustrates a top view of a modified example of the semiconductor device 100.

FIG. 2C illustrates a b-b′ a cross section of a modified example of the semiconductor device 100.

FIG. 3A illustrates an enlarged view of the cross section of the semiconductor device 100.

FIG. 3B illustrates an enlarged view of a cross section of a semiconductor device 100 as a modified example.

FIG. 3C illustrates an enlarged view of a cross section of the semiconductor device 100 as the modified example.

FIG. 4 illustrates an enlarged view of a cross section of a semiconductor device in a comparative example.

FIG. 5 is a flowchart illustrating an example of a manufacturing process of the semiconductor device 100.

FIG. 6A illustrates one example of a manufacturing method of the semiconductor device 100.

FIG. 6B illustrates one example of a manufacturing method of the semiconductor device 100.

FIG. 6C illustrates one example of a manufacturing method of the semiconductor device 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z-axis direction and the −Z-axis direction are directions opposite to each other. When the Z-axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X-axis direction and the Y-axis direction.

In the present specification, a description of a P+ type or an N+ type means a higher doping concentration than that of a P type or an N type, and a description of a P− type or an N− type means a lower doping concentration than that of the P type or the N type.

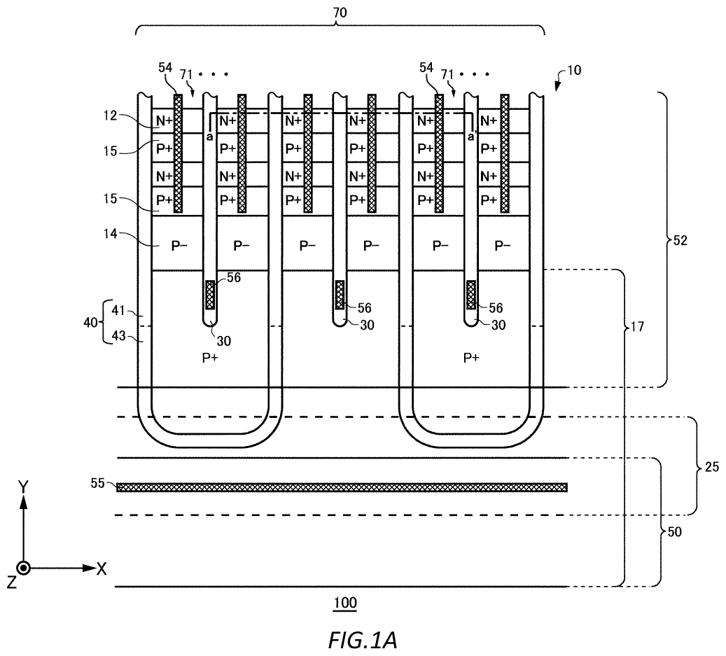

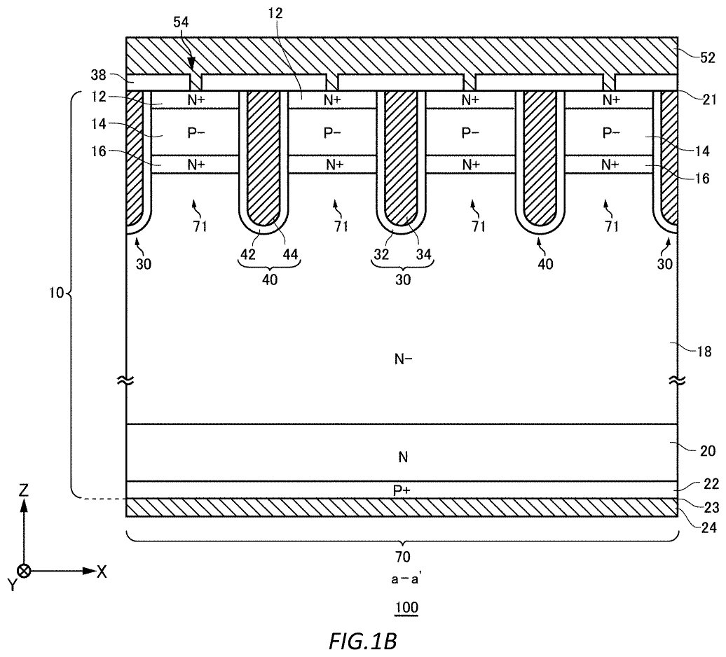

FIG. 1A illustrates an example of the top view of a semiconductor device 100. The semiconductor device 100 in the present example is a semiconductor chip that includes a transistor portion 70. The semiconductor device 100 is not limited to a transistor as long as it is a semiconductor element in which a semiconductor substrate 10 has a MOS gate structure.

The transistor portion 70 is a region obtained by projecting a collector region 22 provided on a back surface side of a semiconductor substrate 10 onto an upper surface of the semiconductor substrate 10. The collector region 22 will be described below. The transistor portion 70 includes a transistor such as an IGBT. In the present example, the transistor portion 70 is an IGBT. It is to be noted that the transistor portion 70 may be other transistors such as a MOSFET.

The present figure illustrates a region around an active portion of the semiconductor device 100 and other regions are omitted. For example, an edge termination structure portion may be provided in a region on a negative side in the Y-axis direction in the semiconductor device 100 in the present example. The edge termination structure portion reduces electric field strength on an upper surface side of the semiconductor substrate 10. The edge termination structure portion has, for example, a guard ring, a field plate, a RESURF, and a structure combining these. It should be noted that although the present example describes an edge on the negative side in the Y-axis direction for convenience, the same applies to other edges of the semiconductor device 100.

The semiconductor substrate 10 is a substrate that is formed of a semiconductor material. The semiconductor substrate 10 may be a silicon substrate or may be a silicon carbide substrate. The semiconductor substrate 10 in the present example is the silicon substrate. It is to be noted that when simply referred to as a top view in the present specification, it means that the upper surface side of the semiconductor substrate 10 is viewed from above. As will be described below, the semiconductor substrate 10 includes a front surface 21 and a back surface 23.

The semiconductor device 100 in the present example includes, at a front surface 21 of the semiconductor substrate 10, a gate trench portion 40, a dummy trench portion 30, an emitter region 12, a base region 14, a contact region 15, and a well region 17. In addition, the semiconductor device 100 in the present example includes an emitter electrode 52 and a gate metal layer 50 which are provided above the front surface 21 of the semiconductor substrate 10. The emitter electrode 52 and the gate metal layer 50 are an example of a front surface side metal layer 53 to be described below. The gate trench portion 40 is an example of the MOS gate structure provided in the semiconductor device 100. It is to be noted that although the semiconductor device 100 of the present example is a transistor including the MOS gate structure, the semiconductor device 100 may alternatively be a diode including the MOS gate structure.

The emitter electrode 52 is provided above the gate trench portion 40, the dummy trench portion 30, the emitter region 12, the base region 14, the contact region 15, and the well region 17. In addition, the gate metal layer 50 is provided above the connection portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may include a barrier layer 60 formed of titanium or titanium compound on a lower layer of the region formed of aluminum and the like. The barrier layer 60 will be described below. The emitter electrode 52 and the gate metal layer 50 are provided separately from each other.

The emitter electrode 52 and the gate metal layer 50 are provided with an interlayer dielectric film 38 sandwiched therebetween, above the semiconductor substrate 10. The interlayer dielectric film 38 is omitted in FIG. 1A. A contact hole 54, a contact hole 55, and a contact hole 56 are provided through the interlayer dielectric film 38.

The contact hole 55 electrically connects the gate metal layer 50 and the gate conductive portion in the transistor portion 70 through the connection portion 25. A plug layer 64 formed of tungsten or the like may be formed inside the contact hole 55. The plug layer 64 will be described below.

The contact hole 56 connects the emitter electrode 52 with a dummy conductive portion inside the dummy trench portion 30. A plug layer 64 formed of tungsten or the like may be formed inside the contact hole 56.

A connection portion 25 is connected to a front surface side metal layer 53 such as the emitter electrode 52 or the gate metal layer 50. In an example, the connection portion 25 is provided between the gate metal layer 50 and the gate conductive portion. The connection portion 25 of the present example may be provided extending in the X-axis direction and electrically connected to the gate conductive portion. The connection portion 25 may also be provided between the emitter electrode 52 and the dummy conductive portion. In the present example, the connection portion 25 is not provided between the emitter electrode 52 and the dummy conductive portion. The connection portion 25 is formed of a conductive material such as polysilicon doped with an impurity. The connection portion 25 in the present example is polysilicon doped with an impurity of the N type (N+). The connection portion 25 is provided above the front surface 21 of the semiconductor substrate 10 via a dielectric film such as an oxide film, or the like.

The gate trench portions 40 are an example of a plurality of trench portions extending in a predetermined extending direction on the front surface 21 side of the semiconductor substrate 10. The gate trench portions 40 are arrayed at a predetermined interval along a predetermined array direction (the X-axis direction in the present example). The gate trench portion 40 in the present example may have two extending portions 41 which extend along an extending direction (the Y-axis direction in the present example) parallel to the front surface 21 of the semiconductor substrate 10 and perpendicular to the array direction, and a connecting portion 43 which connects the two extending portions 41.

At least a portion of the connecting portion 43 is preferably formed in a curved shape. Connecting end portions of the two extending portions 41 of the gate trench portion 40 can reduce electric field strength at the end portions of the extending portions 41. The gate metal layer 50 may be electrically connected to the gate conductive portion through the connection portion 25 in the connecting portion 43 of the gate trench portion 40.

The dummy trench portions 30 are an example of the plurality of trench portions extending in the predetermined extending direction on the front surface 21 side of the semiconductor substrate 10. The dummy trench portion 30 is a trench portion which is electrically connected to the emitter electrode 52. Similar to the gate trench portions 40, the dummy trench portions 30 are arrayed at predetermined intervals along a predetermined array direction (the X-axis direction in the present example). Although the dummy trench portion 30 of the present example has an I shape on the front surface 21 of the semiconductor substrate 10, it may have a U-shape on the front surface 21 of the semiconductor substrate 10 similar to the gate trench portion 40. That is, the dummy trench portion 30 may include two extending portions extending along the extending direction and a connecting portion which connects the two extending portions.

The transistor portion 70 of the present example has a structure in which two gate trench portions 40 and two dummy trench portions 30 are arrayed repetitively. That is, the transistor portion 70 in the present example has the gate trench portions 40 and the dummy trench portions 30 at a ratio of 1:1. For example, the transistor portion 70 includes one dummy trench portion 30 between two extending portions 41.

It is to be noted that the ratio between the gate trench portions 40 and the dummy trench portions 30 is not limited to that in the present example. The ratio of the gate trench portions 40 may be larger than the ratio of the dummy trench portions 30, or the ratio of the dummy trench portions 30 may be larger than the ratio of the gate trench portions 40. The ratio between the gate trench portions 40 and the dummy trench portions 30 may be 2:3, or may be 2:4. In addition, the transistor portion 70 may not have the dummy trench portions 30 with all trench portions being the gate trench portions 40.

The well region 17 is a region of a second conductivity type which is provided in a front surface 21 side of the semiconductor substrate 10 relative to a drift region 18 which will be described below. The well region 17 is an example of the well region provided in a peripheral side of the active portion 120. The well region 17 is of the P+ type as an example. The well region 17 is formed in a predetermined range from an end portion of an active region on a side where the gate metal layer 50 is provided. A diffusion depth of the well region 17 may be deeper than depths of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

The contact hole 54 is formed above each of the emitter region 12 and the contact region 15 in the transistor portion 70. The contact hole 54 is not provided above well regions 17 provided at both ends in the Y-axis direction. In this manner, one or more contact holes 54 are formed in the interlayer dielectric film. The one or more contact holes 54 may be provided extending in the extending direction.

A mesa portion 71 is a mesa portion provided in direct contact with the trench portion in a plane parallel to the front surface 21 of the semiconductor substrate 10. The mesa portion may be a part of the semiconductor substrate 10 sandwiched between two adjacent trench portions, and may be a portion from the front surface 21 of the semiconductor substrate 10 to a depth of the lowermost bottom portion of each trench portion. An extending portion of each trench portion may be defined as one trench portion. That is, the region sandwiched between two extending portions may be defined as a mesa portion.

The mesa portion 71 is provided in direct contact with at least one of the dummy trench portion 30 or the gate trench portion 40 in the transistor portion 70. The mesa portion 71 has the well region 17, the emitter region 12, the base region 14, and the contact region 15 at the front surface 21 of the semiconductor substrate 10. In the mesa portion 71, emitter regions 12 and contact regions 15 are alternately provided in the extending direction.

The base region 14 is a region of the second conductivity type which is provided in the front surface 21 side of the semiconductor substrate 10. The base region 14 is of the P− type as an example. The base regions 14 may be provided at both end portions of the mesa portion 71 in the Y-axis direction at the front surface 21 of the semiconductor substrate 10. Note that FIG. 1A illustrates only one end portion in the Y-axis direction of the base region 14.

The emitter region 12 is a region of a first conductivity type having a higher doping concentration than the drift region 18. The emitter region 12 in the present example is of the N+ type as an example. Examples of a dopant of the emitter region 12 include arsenic (As). The emitter region 12 is provided in direct contact with the gate trench portion 40 at the front surface 21 in the mesa portion 71. The emitter region 12 may be provided to extend in the X-axis direction from one to another of two trench portions sandwiching the mesa portion 71. The emitter region 12 is also provided below the contact hole 54.

In addition, the emitter region 12 may or may not be in direct contact with the dummy trench portion 30. The emitter region 12 in the present example is in direct contact with the dummy trench portion 30.

The contact region 15 is a region of the second conductivity type provided above the base region 14 and having a higher doping concentration than the base region 14. The contact region 15 in the present example is of the P+ type as an example. The contact region 15 in the present example is provided at the front surface 21 in the mesa portion 71. The contact region 15 may be provided in the X-axis direction from one to another of the two trench portions sandwiching the mesa portion 71. The contact region 15 may be or may not be in direct contact with the gate trench portion 40 or the dummy trench portion 30. The contact region 15 in the present example is in direct contact with the dummy trench portion 30 and the gate trench portion 40. The contact region 15 is also provided below the contact hole 54.

FIG. 1B illustrates an example of a cross section a-a′ in FIG. 1A. The cross section a-a′ is an XZ plane which passes through the emitter region 12 in the transistor portion 70. In the cross section a-a′, the semiconductor device 100 in the present example has the semiconductor substrate 10, the interlayer dielectric film 38, the emitter electrode 52, and a collector electrode 24. The collector electrode 24 is an example of a back surface side metal layer provided in direct contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region which has remained without other doping regions formed in the semiconductor substrate 10. That is, a doping concentration in the drift region 18 may be a doping concentration in the semiconductor substrate 10.

A buffer region 20 is a region of the first conductivity type which is provided on a back surface 23 side of the semiconductor substrate 10 relative to the drift region 18. The buffer region 20 in the present example is of the N type as an example. The doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. It should be noted that the buffer region 20 may be omitted.

The collector region 22 is provided below the buffer region 20 in the transistor portion 70. The collector region 22 has the second conductivity type. The collector region 22 in the present example is of the P+ type as an example.

The collector electrode 24 is formed at the back surface 23 of the semiconductor substrate 10. The collector electrode 24 is formed of a conductive material such as metal. The material of the collector electrode 24 may be the same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in direct contact with the gate trench portion 40. The emitter region 12 may or may not be in direct contact with the dummy trench portion 30.

An accumulation region 16 is a region of the first conductivity type which is provided on the front surface 21 side of the semiconductor substrate 10 relative to the drift region 18. The accumulation region 16 in the present example is of the N+ type as an example. It is to be noted that the accumulation region 16 may not be provided.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. An ion implantation dose amount of the accumulation region 16 may be 1.0E+12 cm−2 or more and 1.0E+13 cm−2 or less. Alternatively, the ion implantation dose amount of the accumulation region 16 may be 3.0E+12 cm−2 or more and 6.0E+12 cm−2 or less. Providing the accumulation region 16 can increase a carrier implantation enhancement effect (IE effect) to reduce an on-voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, or the accumulation region 16, each trench portion also passes through these regions to reach the drift region 18. The configuration of the trench portion penetrating the doping region is not limited to the one manufactured in the order of forming the doping region and then forming the trench portion. The configuration of the trench portion passing through the doping region includes a configuration of the doping region being formed between the trench portions after forming the trench portion.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the base region 14 in direct contact on the side of the mesa portion 71 by sandwiching the gate dielectric film 42 in a depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have the same structure as that of the gate trench portion 40. The dummy trench portion 30 has a dummy trench, a dummy dielectric film 32, and a dummy conductive portion 34 which are formed on the front surface 21 side. The dummy dielectric film 32 is formed covering the inner walls of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 in the present example is provided in direct contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may be provided to pass through the interlayer dielectric film 38. A film thickness of the interlayer dielectric film 38 is, for example, 1.0 μm, but is not limited to this. The interlayer dielectric film 38 in the present example may have a first interlayer dielectric film 381 provided to be in direct contact with the front surface 21, and a second interlayer dielectric film 382 provided above the first interlayer dielectric film 381.

The interlayer dielectric film 38 may be a silicon oxide film. The interlayer dielectric film 38 may be a BPSG (Boro-phosphor Silicate Glass) film, may be a BSG (borosilicate glass) film, or may be a PSG (Phosphosilicate glass) film. The interlayer dielectric film 38 may also include a high temperature silicon oxide (HTO: High Temperature Oxide) film. The first interlayer dielectric film 381 and the second interlayer dielectric film 382 may be the same material, or may be different materials. In an example, the first interlayer dielectric film 381 may be a HTO film, and the second interlayer dielectric film 382 may be a BPSG film. The interlayer dielectric film 38 may also be a layered configuration with three or more layers.

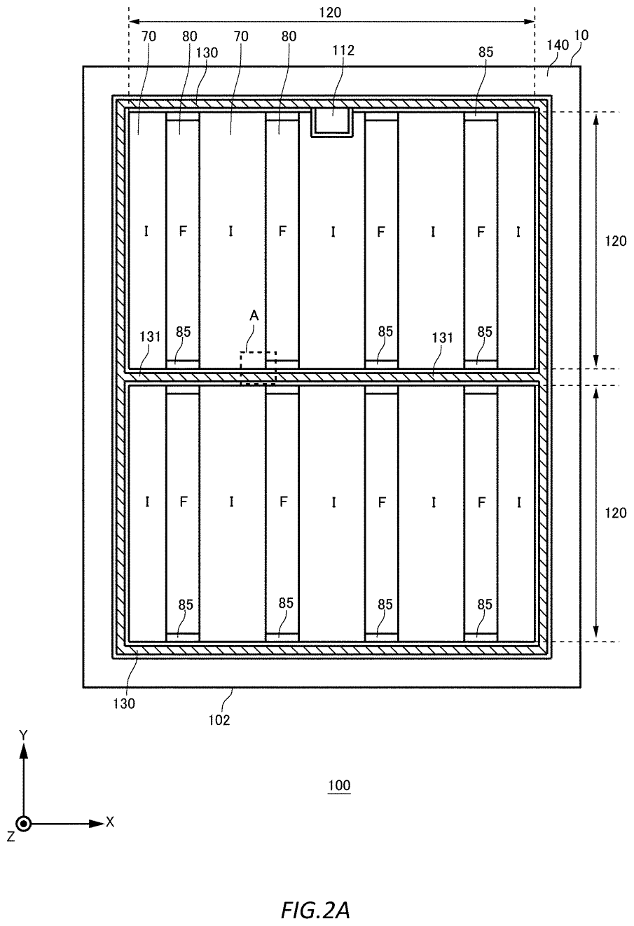

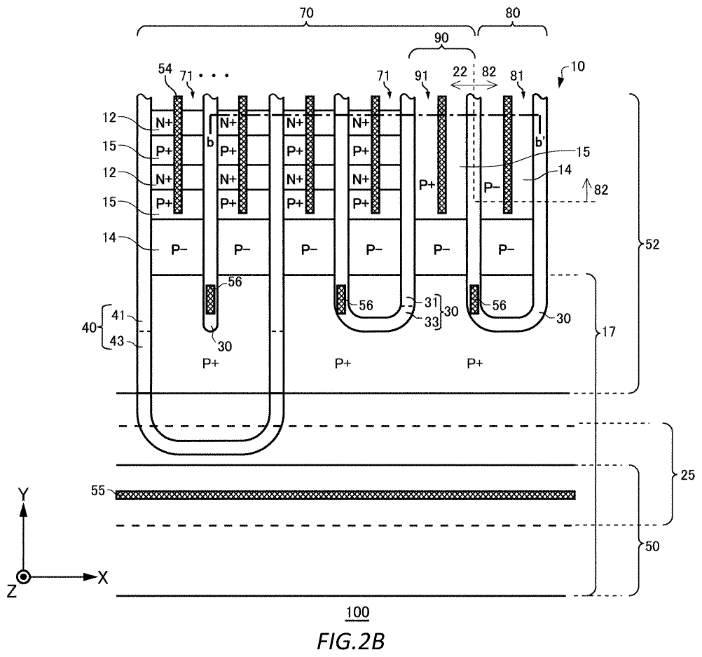

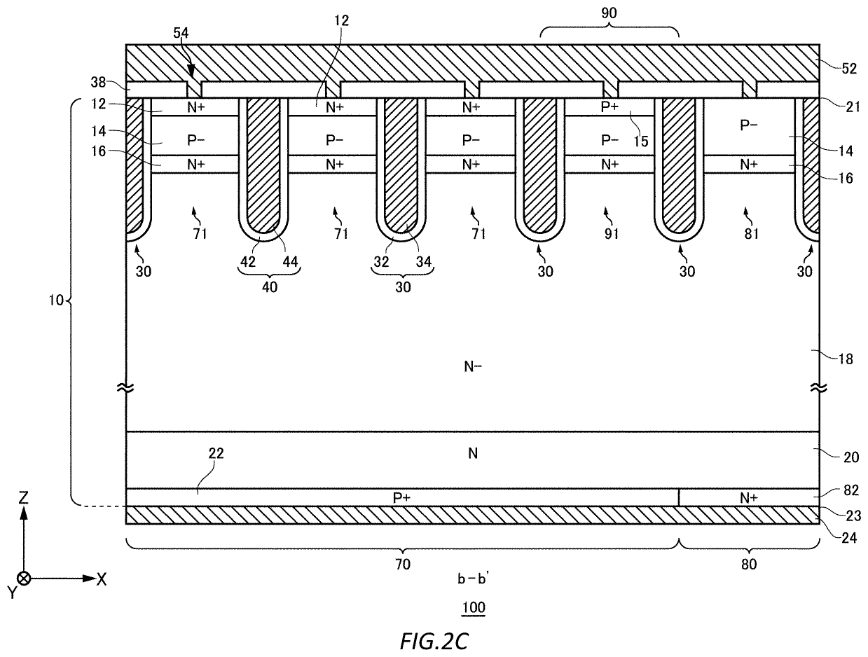

FIG. 2A shows a top view of a modified example of the semiconductor device 100. The present example illustrates merely some members of the semiconductor device 100, and omits some members.

The semiconductor substrate 10 has an end side 102 in a top view. The semiconductor substrate 10 of the present example includes two sets of end sides 102 facing each other in the top view. In the present example, the X axis and the Y axis are parallel to any of the end sides 102.

The semiconductor substrate 10 is provided with an active portion 120. The active portion 120 is a region where a principal current flows in the depth direction between the front surface 21 and the back surface 23 of the semiconductor substrate 10 when the semiconductor device 100 operates. An emitter electrode 52 is provided above the active portion 120, but is omitted in the present figure.

The active portion 120 is provided with at least one of a transistor portion 70 including a transistor element such as an IGBT, or a diode portion 80 including a diode element such as a free wheeling diode (FWD). In the example of FIG. 2A, the transistor portion 70 and the diode portion 80 are alternately arranged along a predetermined array direction (the X-axis direction in the present example) on the front surface 21 of the semiconductor substrate 10. The active portion 120 in another example may be provided with only one of the transistor portion 70 and the diode portion 80.

In the present example, a region where the transistor portion 70 is arranged is denoted by a symbol “I”, and a region where the diode portion 80 is arranged is denoted by a symbol “F”. Each of the transistor portions 70 and the diode portions 80 may have a longitudinal length in the extending direction. In other words, the length of each of the transistor portions 70 in the Y-axis direction is larger than the width in the X-axis direction. Similarly, the length of each of the diode portions 80 in the Y-axis direction is larger than the width in the X-axis direction. The extending direction of the transistor portion 70 and the diode portion 80, and the longitudinal direction of each trench portion described below may be the same.

The diode portion 80 is a region obtained by projecting a cathode region 82 provided in the back surface 23 side of the semiconductor substrate 10 onto the upper surface of the semiconductor substrate 10. The cathode region 82 will be described below. On the back surface 23 of the semiconductor substrate 10, a P+ type of collector region 22 may be provided in a region other than the cathode region 82. In the present specification, the diode portion 80 may also include an extension region 85 where the diode portion 80 extends to a gate runner described below in the Y-axis direction. On the back surface 23 of the extension region 85, the collector region 22 may be provided.

The semiconductor device 100 may have one or more pads above the semiconductor substrate 10. The semiconductor device 100 of the present example has a gate pad 112. The semiconductor device 100 may include a pad such as an anode pad and a cathode pad. In the case of the present example, each pad is arranged near the end side 102. The vicinity of the end side 102 refers to a region between the end side 102 and the emitter electrode 52 in a top view. When the semiconductor device 100 is mounted, each pad may be connected to an external circuit through a wiring such as a wire. Regarding the arrangement position, each pad may not be arranged near the end side 102.

A gate potential is applied to the gate pad 112. The gate pad 112 is electrically connected to the gate conductive portion 44 of the gate trench portion 40 of the active portion 120. The semiconductor device 100 includes a gate runner that connects the gate pad 112 and the gate trench portion 40. In FIG. 2A, the gate runner is hatched with diagonal lines.

The gate runner of the present example has an outer circumferential gate runner 130 and an inter-active-portion gate runner 131. The gate runner may be composed of either one of the gate metal layer 50 or the connection portion 25, or may be composed of a combination of both as appropriate. The outer circumferential gate runner 130 and the inter-active-portion gate runner 131 may have the same configuration or may have a different configuration. The outer circumferential gate runner 130 is arranged between the active portion 120 and the end side 102 of the semiconductor substrate 10 in a top view. The outer circumferential gate runner 130 of the present example surrounds the active portion 120 in the top view. A region surrounded by the outer circumferential gate runner 130 in the top view may be the active portion 120. Further, the outer circumferential gate runner 130 is connected to the gate pad 112. The outer circumferential gate runner 130 is arranged above the semiconductor substrate 10. The outer circumferential gate runner 130 may be composed of the gate metal layer 50 and the connection portion 25.

The inter-active-portion gate runner 131 is provided between a plurality of active portions 120. In FIG. 2A, two active portions 120 are arranged side by side in the Y-axis direction. Providing the inter-active-portion gate runner 131 between the plurality of active portions 120 inside the semiconductor substrate 10 can reduce a variation in wiring length from the gate pad 112 for each region of the semiconductor substrate 10.

The inter-active-portion gate runner 131 is connected to the gate trench portion of the active portion 120. The inter-active-portion gate runner 131 is arranged above the semiconductor substrate 10. The inter-active-portion gate runner 131 of the present example is composed of the gate metal layer 50 and the connection portion 25. The gate metal layer 50 may be a metal layer including aluminum or the like.

The inter-active-portion gate runner 131 may be connected to the outer circumferential gate runner 130. The inter-active-portion gate runner 131 of the present example is provided extending in the X-axis direction from one outer circumferential gate runner 130 to another outer circumferential gate runner 130 substantially at the center of the Y-axis direction, so as to cross the active portion 120. When the active portion 120 is divided by the inter-active-portion gate runner 131, the transistor portion 70 and the diode portion 80 may be alternately arranged in the X-axis direction in each divided region.

An edge termination structure portion 140 is provided at the front surface 21 of the semiconductor substrate 10. The edge termination structure portion 140 is provided between the active portion 120 and the end side 102 in a top view. The edge termination structure portion 140 in the present example is arranged between the outer circumferential gate runner 130 and the end side 102. The edge termination structure portion 140 reduces electric field strength on the front surface 21 side of the semiconductor substrate 10. The edge termination structure portion 140 may include at least one of a guard ring, a field plate, and a RESURF which are annularly provided to enclose the active portion 120.

FIG. 2B illustrates a top view of the modified example of the semiconductor device 100. The semiconductor device 100 of the present example includes the transistor portion 70 and a diode portion 80. The present figure is an enlarged view of the upper surface of the region A in FIG. 2A.

The semiconductor device 100 of the present example includes a gate trench portion 40, a dummy trench portion 30, an emitter region 12, a base region 14 a contact region 15, and a well region 17 provided inside the front surface 21 side of the semiconductor substrate 10. The gate trench portion 40 and the dummy trench portion 30 each are an example of the trench portion.

Similar to the gate trench portion 40, the dummy trench portion 30 of the present example may have a U-shape on the front surface 21 of the semiconductor substrate 10. That is, the dummy trench portion 30 may have two extending portions 31 which extend along the extending direction and a connecting portion 33 which connects two extending portions 31.

The semiconductor device 100 of the present example includes the emitter electrode 52 and the gate metal layer 50 provided above the front surface 21 of the semiconductor substrate 10. The emitter electrode 52 and the gate metal layer 50 are provided separated from each other. The transistor portion 70 in the present example includes a boundary portion 90 that is positioned at a boundary between the transistor portion 70 and the diode portion 80. However, the semiconductor device 100 may not include the boundary portion 90.

The boundary portion 90 is a region which is provided in the transistor portion 70 and is in direct contact with the diode portion 80. The boundary portion 90 includes the contact region 15 in the front surface 21 of the semiconductor substrate 10. The boundary portion 90 of the present example does not include the emitter region 12. In an example, the trench portions in the boundary portion 90 are the dummy trench portions 30. The boundary portion 90 of the present example is arranged such that both ends thereof in the X-axis direction become the dummy trench portions 30.

The contact hole 54 is provided above the base region 14 in the diode portion 80. The contact hole 54 is provided above the contact region 15 in the boundary portion 90. No contact holes 54 are provided above the well regions 17 provided at both ends of the Y-axis direction.

The mesa portion 91 is provided in the boundary portion 90. The mesa portion 91 includes the contact region 15 in the front surface 21 of the semiconductor substrate 10. The mesa portion 91 in the present example includes the base region 14 and the well region 17 in the negative side of the Y-axis direction.

The mesa portion 81 is provided in a region sandwiched between the dummy trench portions 30 adjacent to each other in the diode portion 80. The mesa portion 81 has the base region 14 at the front surface 21 of the semiconductor substrate 10. The mesa portion 81 of the present example includes the well region 17 on the negative side in the Y-axis direction.

The emitter region 12 is provided in the mesa portion 71, but may not need to be provided in the mesa portion 81 and the mesa portion 91. The contact region 15 is provided in the mesa portion 71 and the mesa portion 91, but may not need to be provided in the mesa portion 81.

FIG. 2C shows a b-b′ cross section of a modified example of the semiconductor device 100. This figure corresponds to the b-b′ cross section of FIG. 2B. The semiconductor device 100 of the present example includes the collector region 22 and the cathode region 82 on the back surface 23 side of the buffer region 20.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

The accumulation region 16 is provided in the transistor portion 70 and the diode portion 80. The accumulation region 16 in the present example is provided at entire surfaces of the transistor portion 70 and the diode portion 80. It is to be noted that the accumulation region 16 may not need to be provided in the diode portion 80.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the boundary portion 90 in the present example.

The semiconductor device 100 may be a power semiconductor device for performing power control and the like. The semiconductor device 100 of the present example may have a vertical semiconductor structure in which a back surface side metal layer is provided on the back surface 23 side of the semiconductor substrate 10. It is to be noted that the semiconductor device 100 may alternatively have a horizontal semiconductor structure in which the metal layer is not provided on the back surface 23 side.

It is to be noted that in the present example, an RC-IGBT having a trench gate structure is described as an example of the semiconductor device 100. It is to be noted that the semiconductor device 100 may be a semiconductor device having a planar gate structure, or may be other semiconductor devices such as a diode. The semiconductor device 100 may include an N-channel MOSFET or P-channel MOSFET.

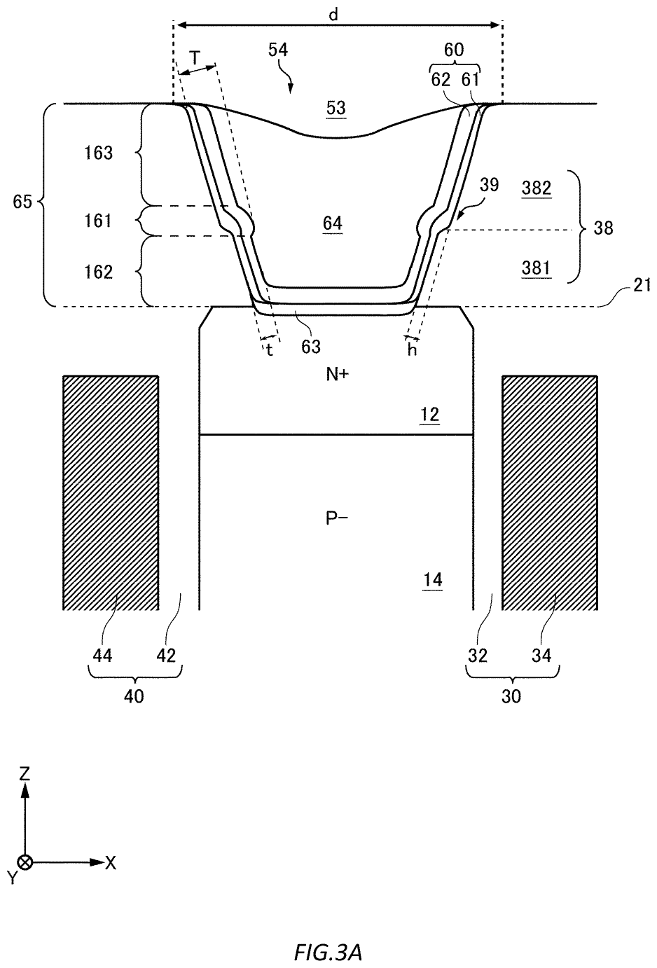

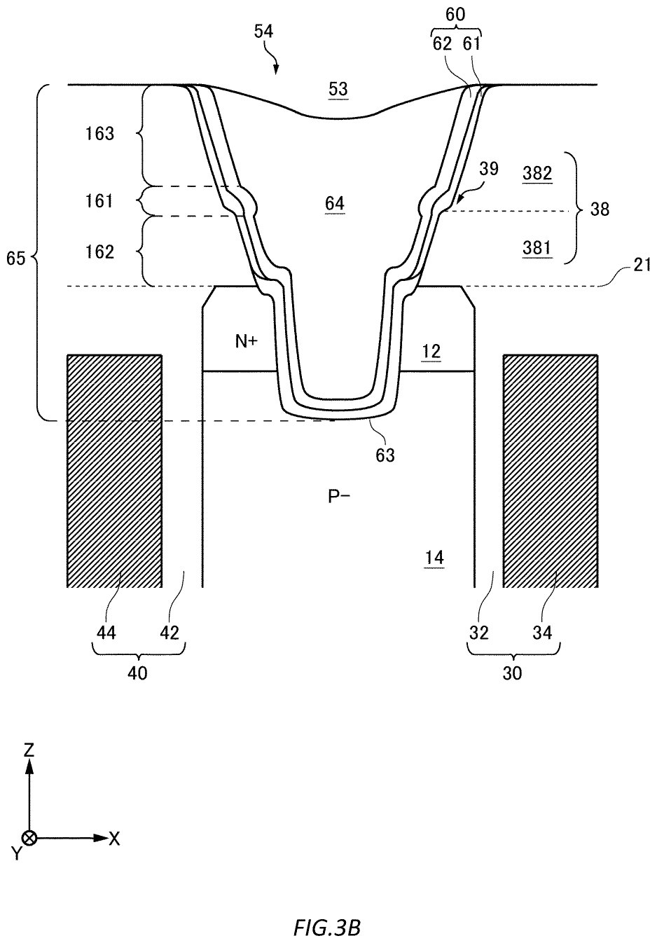

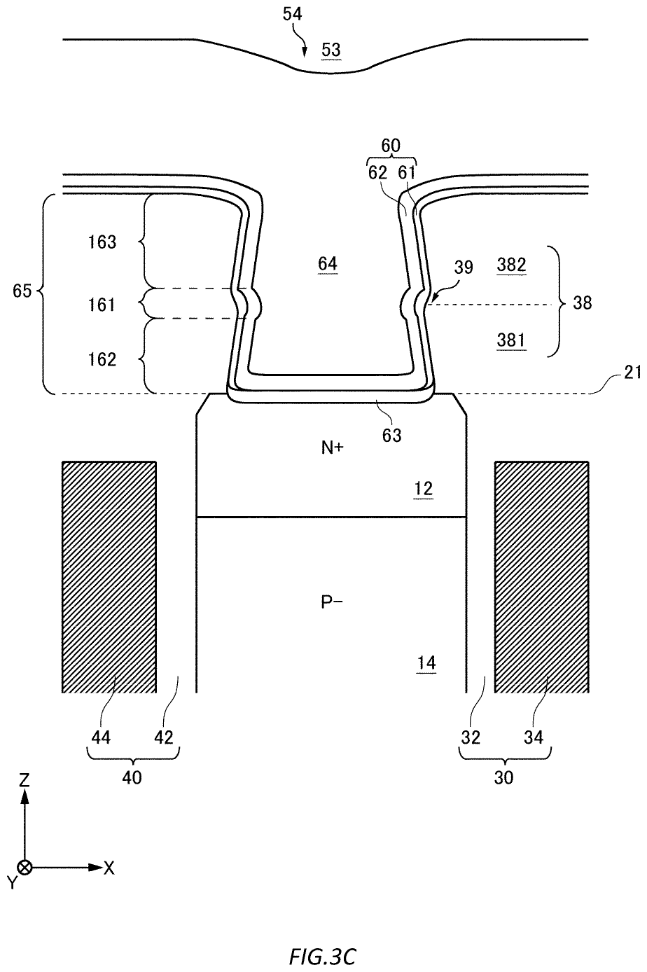

FIG. 3A is an enlarged view of a cross section of the semiconductor device 100. In the present example, an enlarged view of a cross section near the contact portion 65 provided in the contact hole 54 is shown. The cross section in the present example is the XZ cross section which passes through the emitter region 12 at a front surface 21 of a semiconductor substrate 10. The contact portion 65 includes a barrier layer 60, a silicide layer 63 and a plug layer 64.

In the present specification, the structure near the contact portion 65 may be described using the contact hole 54, but the similar structure may be adopted for other contact holes such as the contact hole 55 and the contact hole 56. That is, the barrier layer 60, the silicide layer 63 and the plug layer 64 may be provided in other contact holes such as the contact hole 55 and the contact hole 56.

The contact hole 54 has a stepped portion 39 on the sidewall. The stepped portion 39 may be formed at a boundary between the first interlayer dielectric film 381 and the second interlayer dielectric film 382. The stepped portion 39 may be a region that is the sidewall of the contact hole 54 including at least one inflection point. The stepped portion 39 may be a region formed in a step-like manner at the boundary between the first interlayer dielectric film 381 and the second interlayer dielectric film 382.

The height h of the stepped portion 39 may be 15% or less, or 10% or less, or 5% or less of an opening width d of the contact hole 54 in the array direction on the upper surface of the interlayer dielectric film 38. In the present example, the height h of the stepped portion 39 may be 120 nm or less, or 80 nm or less, or 40 nm or less. In the present specification, the height h of the stepped portion 39 may refer to a height up to the sidewall of the first interlayer dielectric film 381, which has been measured in a direction perpendicular to the tangential direction of the sidewall of the second interlayer dielectric film 382.

In the present example, the sidewall of the contact hole 54 has a slope that is a forward taper. The taper angle of the sidewall of the contact hole 54 may be from 70 degrees to 90 degrees.

In the present example, the aspect ratio of the contact hole 54 may be 2 or more, or may be 5 or more. The aspect ratio of the contact hole 54 may be from 0.5 to 10. In the present specification, the aspect ratio of the contact hole 54 is a numerical value obtained by dividing the depth of the contact hole 54 in the depth direction of the semiconductor substrate 10 by the opening width d of the contact hole 54 on the upper surface of the interlayer dielectric film 38.

The barrier layer 60 is provided on the silicide layer 63 in the contact hole 54. The barrier layer 60 is provided on the bottom surface of the contact hole 54 and the sidewall of the interlayer dielectric film 38. The barrier layer 60 in the present example is provided on the upper surface of the silicide layer 63 and the sidewall of the interlayer dielectric film 38 in the contact hole 54. The barrier layer 60 may include titanium (Ti) or tantalum (Ta). The barrier layer 60 in the present example has a first barrier metal layer 61 and a second barrier metal layer 62.

The barrier layer in the present example has a first region 161 that is a region in direct contact with the stepped portion 39, a second region 162 that is a region on a lower side than the first region 161, being in direct contact with the sidewall of the contact hole 54, and a third region 163 that is a region on an upper side than the first region 161, being in direct contact with the sidewall of the contact hole 54.

The first barrier metal layer 61 is provided on the sidewall of the interlayer dielectric film 38. The first barrier metal layer 61 may be provided on the bottom surface of the contact hole 54. The first barrier metal layer 61 may include at least one of titanium (Ti), tantalum (Ta), titanium nitride (TIN) or tantalum nitride (TaN). As an example, the first barrier metal layer 61 is Ti.

A film thickness of the first barrier metal layer 61 in the first region 161 may be from 2 nm to 119 nm. A film thickness of the first barrier metal layer 61 in the second region 162 may be from 0.5 nm to 113 nm. Herein, a film thickness of the first barrier metal layer 61 may refer to a thickness of the first barrier metal layer 61, which has been measured in a direction perpendicular to the tangential direction of the sidewall of the contact hole 54.

The second barrier metal layer 62 is stacked on the first barrier metal layer 61 in the contact hole 54. The second barrier metal layer 62 is provided on the bottom surface of the contact hole 54 to be stacked on the silicide layer 63 provided on the front surface 21 of the semiconductor substrate 10. The second barrier metal layer 62 may include at least one of titanium nitride (TiN) or tantalum nitride (TaN). As an example, the second barrier metal layer 62 is TiN.

In the first region 161, the film thickness of the second barrier metal layer 62 may be from 2 nm to 119 nm. In the second region 162, the film thickness of the second barrier metal layer 62 may be from 0.5 nm to 113 nm. Herein, the film thickness of the second barrier metal layer 62 may refer to a thickness of the second barrier metal layer 62, which has been measured in a direction perpendicular to the tangential direction of the surface of the first barrier metal layer 61.

The film thickness of the second barrier metal layer 62 may be thicker than the film thickness of the first barrier metal layer 61 above the stepped portion 39. The film thickness of the second barrier metal layer 62 may be thinner than the film thickness of the first barrier metal layer 61 below the stepped portion 39.

The silicide layer 63 is provided on the upper surface of the semiconductor substrate 10 below the contact hole 54. The silicide layer 63 in the present example is provided on the upper surface of the semiconductor substrate 10. The silicide layer 63 is formed by annealing the first barrier metal layer 61. The silicide layer 63 in the present example is a titanium silicide layer formed by annealing Ti deposited on the bottom surface of the contact hole 54 as the first barrier metal layer 61. A portion of the first barrier metal layer 61 may remain without being silicided on the bottom surface of the contact hole 54.

The plug layer 64 is provided on the barrier layer 60 in the contact hole 54. The plug layer 64 may be provided in direct contact with the second barrier metal layer 62 in the contact hole 54. The plug layer 64 is a conductive material that is filled inside the contact hole 54. The material of the plug layer 64 may be different from that of the front surface side metal layer 53. For example, the material of the plug layer 64 is tungsten. The material of the plug layer 64 may be molybdenum. The plug layer 64 may not be provided, and the front surface side metal layer 53 may be embedded within the contact hole 54.

The film thickness of the barrier layer 60 in the first region 161 is thicker than the film thickness of the barrier layer 60 in the second region 162. Herein, the film thickness of the barrier layer 60 may refer to a distance from the sidewall of the contact hole 54 to the surface of the barrier layer 60 in a direction perpendicular to the tangential direction of the sidewall of the contact hole 54.

When the maximum film thickness of the barrier layer 60 in the first region 161 is T, and the minimum film thickness of the barrier layer 60 in the second region 162 is t, 0.3T≤t≤0.95T may be satisfied, or 0.5T≤t≤0.9T may be satisfied. That is, the film thickness of the barrier layer 60 may be uniform in the first region 161 and the second region 162. In the present specification, the film thickness being “uniform” means that 0.3T≤t≤0.95T may be satisfied, 0.5T≤t≤0.9T may be satisfied, or 0.5T≤t≤0.8T may be satisfied. The film thickness T of the barrier layer 60 in the first region 161 may be from 3 nm to 120 nm.

The film thickness of the barrier layer 60 above the stepped portion 39 may be thicker than the film thickness of the barrier layer 60 below the stepped portion 39. In an example, the film thickness of the barrier layer 60 above the stepped portion 39 may be from 1 nm to 115 nm. The film thickness of the barrier layer 60 below the stepped portion 39 may be from 1 nm to 114 nm.

Two or more stepped portions 39 may be provided. By providing two or more stepped portions 39, a plurality of first regions 161 may be provided. Among the provided plurality of first regions 161, on the upper side than the first region 161 closest to the upper surface of the interlayer dielectric film 38, the region in direct contact with the sidewall of the contact hole 54 may be the third region 163, or the region in direct contact with the sidewall of the contact hole 54, which is a region different from the first region 161 and the third region 163, may be the second region 162.

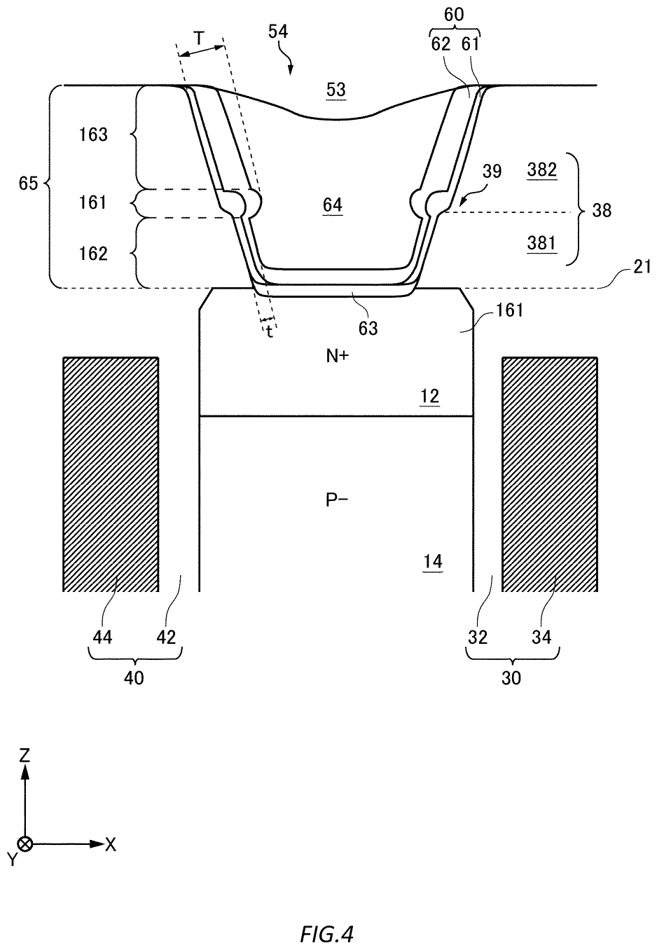

Herein, FIG. 4 is an enlarged view of the cross section near the contact portion in the comparative example. In the comparative example, a difference between the film thickness of the barrier layer 60 above the stepped portion 39 and the film thickness of the barrier layer 60 below the stepped portion 39 is great. In this manner, when there is a great difference in the film thickness of the barrier layer 60, during annealing process or other heat treatment, stress concentration may occur in the portion below the stepped portion 39 where the film thickness is thin, so there is a risk of causing the barrier layer 60 to break and exposing a portion of the semiconductor substrate 10. In such a case, there is a risk that the fluoride used in the subsequent formation of the plug layer 64 may invade the semiconductor substrate 10 and affect the overall performance of the semiconductor device.

On the other hand, the film thickness of the barrier layer 60 in the semiconductor device 100 is uniform in the example. Accordingly, stress concentration does not occur during heat treatment, and rupture of the barrier layer 60 can be suppressed, thus being capable of ensuring the performance of the semiconductor device 100.

FIG. 3B is an enlarged view of a cross section of a semiconductor device 100 as a modified example. In the present example, the enlarged view of the cross section in the vicinity of a contact hole 54 is shown. The cross section in the present example is the XZ cross section which passes through the emitter region 12 at a front surface 21 of a semiconductor substrate 10. The semiconductor device 100 in the present example differs from the example in FIG. 3A in a point of including a trench contact portion as the contact portion 65.

The trench contact portion includes the contact hole 54 and is provided so as to extend from the front surface 21 of the semiconductor substrate 10 in the depth direction of the semiconductor substrate 10. The lower end of the trench contact portion in the present example is deeper than the lower end of the emitter region 12. A lower end of the trench contact portion may be shallower than the lower end of the emitter region 12. In the present example, the lower end of the trench contact portion contacts the base region 14, but may contact a plug region of a second conductivity type of a higher doping concentration than that of the base region 14.

The barrier layer 60 may have the first barrier metal layer 61, the second barrier metal layer 62, and the silicide layer 63 in the trench contact portion. The first barrier metal layer 61 is provided to contact the sidewall of the interlayer dielectric film 38. The silicide layer 63 is provided to contact the sidewall of the semiconductor substrate 10 and the front surface 21 of the semiconductor substrate 10 in the trench contact portion.

The second barrier metal layer 62 is provided to be stacked on the first barrier metal layer 61, which is provided to contact the sidewall of the interlayer dielectric film 38, and the silicide layer 63, which is provided to contact the sidewall and the front surface 21 of the semiconductor substrate 10. The plug layer 64 is provided inside the second barrier metal layer 62 in the contact hole 54.

FIG. 3C is an enlarged view of the cross section of the semiconductor device 100 as the modified example. In the present example, the enlarged view of the cross section in the vicinity of a contact hole 54 is shown. The cross section in the present example is the XZ cross section which passes through the emitter region 12 at a front surface 21 of a semiconductor substrate 10.

The semiconductor device 100 in the present example differs from the example in FIG. 3A in a point that the sidewall of the contact hole 54 has an inverted taper. The taper angle of the sidewall of the contact hole 54 may be from 90 degrees to 110 degrees.

As shown in FIG. 3C, the barrier layer 60 including the first barrier metal layer 61 and the second barrier metal layer 62 may be formed between the interlayer dielectric film 38 and the front surface side metal layer 53. In addition to being formed inside the contact hole 54, the barrier layer 60 may be formed in a region other than the contact hole 54, between the interlayer dielectric film 38 and the front surface side metal layer 53. The plug layer 64 may be formed between the interlayer dielectric film 38 and the front surface side metal layer 53. The plug layer 64 may be formed between the barrier layer 60 and the front surface side metal layer 53 as shown in FIG. 3C.

Although the present example has described that the normal contact portion 65 is included in any case, the similar configuration may be used for the semiconductor device 100 with a multilayer wiring structure, for example. For the configurations of the contact hole 54, the contact hole 55 and the contact hole 56, the contact holes may be not only in a linear shape as shown in the present example, but may be configured in a hole with the dimensions in the array direction and the extending direction being approximately the same, or configured in a square shape, an elliptical shape, a rectangular shape, a shape also extending in the array direction with respect to contact holes extending in the extending direction, or a lattice shape that combines a plurality of contact holes extending in the array direction and a plurality of contact holes extending in the extending direction.

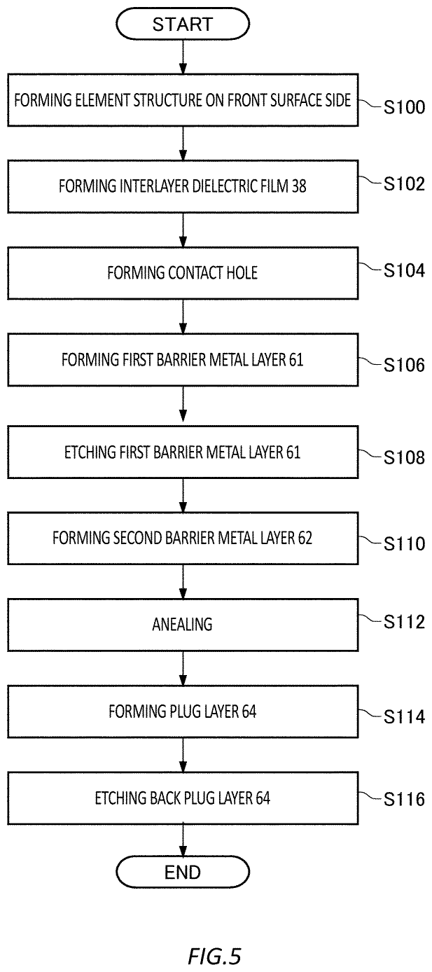

FIG. 5 is a flowchart illustrating an example of a manufacturing process of the semiconductor device 100. In Step S100, an element structure on the front surface 21 side of the semiconductor device 100 is formed. Step S100 may include a process of forming the dummy trench portion 30 and the gate trench portion 40 as the element structure on the front surface 21 side. Step S100 may include a process of forming, as the element structure on the front surface 21 side, the base region 14, the emitter region 12, the contact region 15, and the like by performing ion implantation with respect to the semiconductor substrate 10.

In Step S102, the interlayer dielectric film 38 is formed above the semiconductor substrate 10. The interlayer dielectric film 38 may be formed by stacking a plurality of dielectric films. In the present example, the interlayer dielectric film 38 may be formed by including a first interlayer dielectric film 381 that is a HTO film and a second interlayer dielectric film 382 that is a BPSG film as an example.

In step S104, the contact holes are formed by etching the interlayer dielectric film 38. In step S104, the contact holes such as the contact hole 54, the contact hole 55, and the contact hole 56 may be formed on the interlayer dielectric film 38. The etching method of the contact holes may be selected as either of dry etching or wet etching, or both.

In step S104, as an example of etching, there is a method in which dry etching is firstly performed to form the contact holes, then the contact holes are processed with hydrofluoric acid or dilute hydrofluoric acid for approximately 5 to 500 seconds in order to remove etching residue in contact holes 54, 55 and 56 or to remove natural oxide film on the exposed surface of the semiconductor substrate 10. The processing time of wet etching may be set arbitrarily in consideration of the interlayer dielectric film type or quality, hydrofluoric acid concentration, processing conditions, and desired contact shape dimensions. The dry etching processing and wet etching process may be performed consecutively, or a separate structure forming process may be performed between the two processes.

In each contact hole, a stepped portion 39 may be formed at the boundary between the first interlayer dielectric film 381 and the second interlayer dielectric film 382. Generally, when the etching rate difference between the plurality of interlayer dielectric films employed is great, and when the etching processing time is long, the step shape of the stepped portion 39 becomes larger.

In step S104, by controlling the formation time and formation conditions of the contact holes 54, 55 and 56, the height h of the stepped portion 39 can be set to 15% or less of the opening width d of each contact hole on the upper surface of the interlayer dielectric film 38. When the first barrier metal layer 61 and the second barrier metal layer 62 are formed by sputtering in a contact hole having an aspect ratio of the degree shown in the present embodiment, and the film thickness of each barrier metal layer film is the film thickness of the degree shown in the present embodiment, by setting the height h of the stepped portion 39 to 15% or less of the opening width d of each contact hole on the upper surface of the interlayer dielectric film 38, a uniform barrier layer 60 can be formed.

In step S106, the first barrier metal layer 61 Is formed. The first barrier metal layer 61 in the present example is a Ti film formed by sputtering. In the present example, although the case where a Ti film is formed as the first barrier metal layer 61 is described, the first barrier metal layer 61 may be formed using different types of metal (for example, Ta or the like). When forming the first barrier metal layer 61, it is desirable that no natural oxide film or the like is formed on the surface of the semiconductor substrate 10 on the bottom surface inside the contact holes 54, 55 and 56, leaving the semiconductor substrate 10 exposed.

In step S108, the first region 161 of the first barrier metal layer 61 is etched. Etching may be wet etching or may be dry etching. By etching the first region 161, the film thickness of the first barrier metal layer 61 provided to be thickened in the first region 161 that contacts the stepped portion 39 can be reduced. When etching the first barrier metal layer 61, it is desirable to selectively remove a portion of or the entire first barrier metal layer 61 at the sidewall portion of the contact holes 54, 55 and 56, leaving the first barrier metal layer 61 on the bottom surface.

As an example of the etching method in step S108, when the film thickness of the first barrier metal layer 61 at the sidewall portion is relatively thin compared to the film thickness of the first barrier metal layer 61 on the bottom surface, a method is included, in which the etching time or etching conditions are selected so that the first barrier metal layer 61 of the sidewall portion is removed and the first barrier metal layer of the bottom surface remains. As another example, a method, in which the first barrier metal layer on the bottom surface is made into a silicide layer 63 by performing annealing process after the formation of the first barrier metal layer 61, and the first barrier metal layer at the sidewall portion is selectively removed using the etching rate difference between the first barrier metal layer 61 and the silicide layer 63, or a method, in which the first barrier metal layer 61 at the sidewall portion is lifted off by employing conditions for etching the interlayer dielectric film in wet etching and etching the interlayer dielectric film at the sidewall portion, is included. The step S108 may be omitted.

In step S110, the second barrier metal layer 62 is formed on the first barrier metal layer 61. The second barrier metal layer 62 may be formed to be stacked on the first barrier metal layer 61 on the bottom surface and the sidewall of the contact hole 54. In the present example, the second barrier metal layer 62 is a TiN film formed by sputtering or a CVD (Chemical Vapor Deposition) method.

In step S112, the semiconductor substrate 10 is annealed under a nitrogen atmosphere. An annealing temperature may be from 300° C. to 1100° C. The atmosphere during the annealing process may be an atmosphere that contains oxygen, an atmosphere pressurized, or an atmosphere of vacuum. The annealing of the present example is performed after forming the second barrier metal layer 62. In the present example, annealing may be performed prior to forming the second barrier metal layer 62. By undergoing annealing in step S112, the portion of the first barrier metal layer 61 in direct contact with the semiconductor substrate 10 is solicited to form the silicide layer 63.

In step S114, the plug layer 64 is formed. In the present example, tungsten is formed to embed the inside of the contact hole 54 by the CVD method. The barrier layer 60 may function as an anti-metal diffusion layer during the formation of the plug layer 64. By covering the sidewall and bottom surface of the contact hole 54 with the barrier layer 60, the material gases of the plug layer 64 can be prevented from entering the semiconductor substrate 10 side when the plug layer 64 is formed by CVD. A case of using a material such as molybdenum for the plug layer 64, or a case of using sputtering or the evaporation method as the manufacturing method may be applied.

In step S116, the plug layer 64 is etched back. Accordingly, an unnecessary tungsten film outside the contact hole 54 may be removed. Etching back may be performed by dry etching or CMP (Chemical Mechanical Polishing). At a time of removing the tungsten film, the first barrier metal layer 61 and the second barrier metal layer 62 on the interlayer dielectric film 38 may also be removed. The first barrier metal layer 61 and the second barrier metal layer 62 on the interlayer dielectric film 38 may be removed by a separate process from the etchback of the plug layer 64. The etchback of the barrier layer 60 and the plug layer 64 may be omitted.

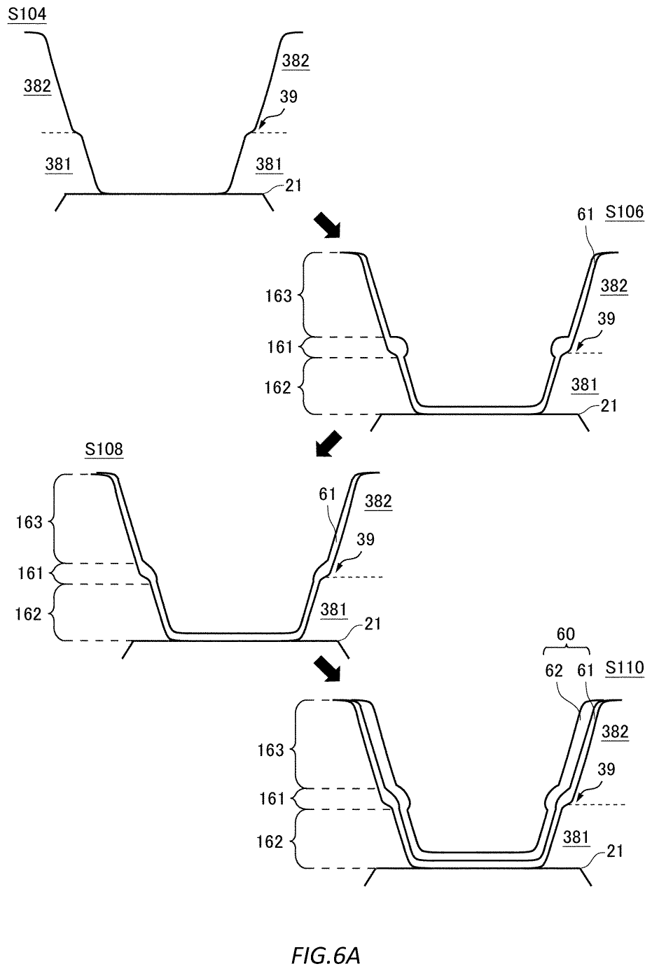

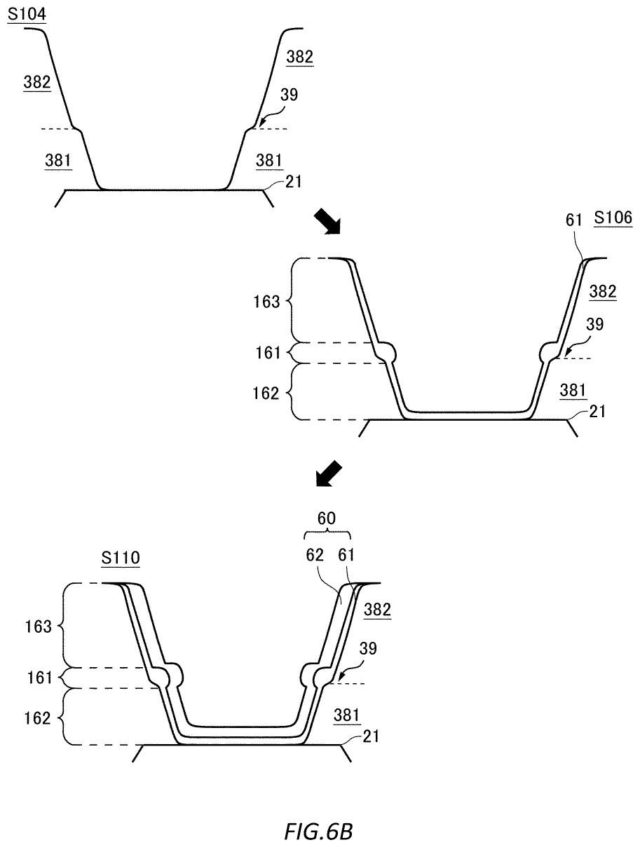

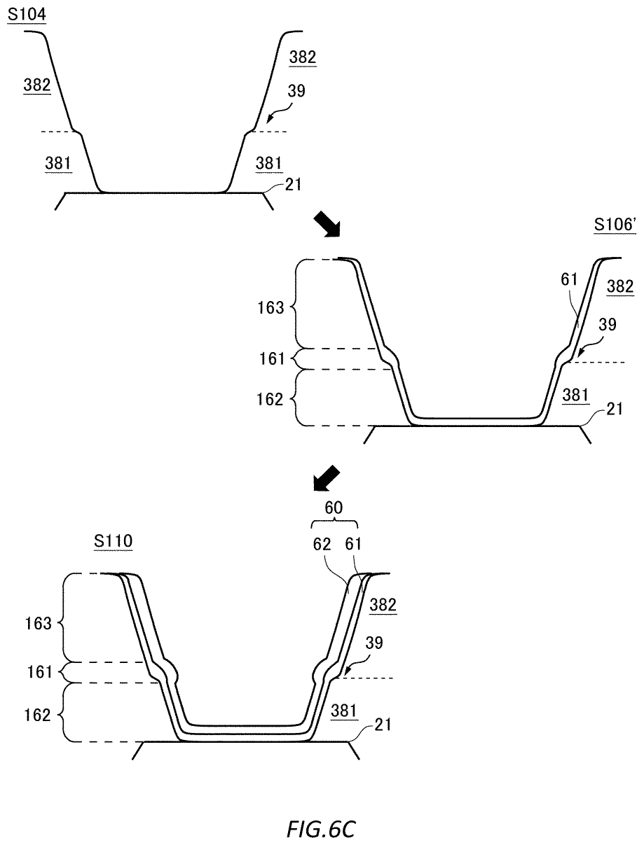

FIG. 6A illustrates one example of a manufacturing method of a semiconductor device 100. In the present example, the cross section near the contact hole 54 is shown to follow the flowchart of the manufacturing method shown in FIG. 5.

In step S104, the contact holes are formed by etching the interlayer dielectric film 38. In the present example, the interlayer dielectric film 38 has a first interlayer dielectric film 381 and a second interlayer dielectric film 382. The first interlayer dielectric film 381 and the second interlayer dielectric film 382 may each be formed of different materials. When the first interlayer dielectric film 381 and the second interlayer dielectric film 382 are each formed of different materials or when the composition ratio, film quality, etc. are different even for the same type of material, etching methods and etching conditions with different etching rates are employed to form the stepped portion 39 on the sidewall of the contact hole 54. After forming the stepped portion 39, the height h of the stepped portion 39 may be reduced or the stepped portion 39 may be removed by applying the etching method in which the etching rate of the side with a narrow opening width relative to the plurality of interlayer dielectric films 38 is faster, or a reverse sputtering method using argon as an example.

In step S106, the first barrier metal layer 61 is formed on the sidewall of the interlayer dielectric film 38 and the upper surface of the semiconductor substrate 10. In the present example, the first barrier metal layer 61 is formed on the upper surface of the front surface 21. The first barrier metal layer 61 may be formed on the upper surface of the interlayer dielectric film 38.

The first barrier metal layer 61 is formed by sputtering. Accordingly, the film thickness of the first barrier metal layer 61 is formed to be thicker in the vicinity of the stepped portion 39 than in other regions. When the second barrier metal layer 62 is formed by sputtering in this state, there is a risk that the second barrier metal layer 62 will not be formed with sufficient thickness below the stepped portion 39 due to the effect of the thickly formed first barrier metal layer 61 near the stepped portion 39.

Therefore, in step S108, the film thickness of the first barrier metal layer 61 near the stepped portion 39 is reduced by etching the first region 161 of the first barrier metal layer 61. Etching may be wet etching or may be dry etching such as reverse sputtering using argon.

In the subsequent step S110, a second barrier metal layer 62 is formed on the first barrier metal layer 61. In the present example, the second barrier metal layer 62 is a TiN film formed by sputtering. In the present example, the thickened first barrier metal layer 61 near the stepped portion 39 is removed in S108, so the second barrier metal layer 62 is formed with sufficient thickness even below the stepped portion 39.

Specifically, among the barrier layer 60, when the maximum film thickness of the barrier layer 60 in the first region 161 provided in direct contact with the stepped portion 39 is T, and the minimum film thickness of the barrier layer 60 in the second region 162 provided in direct contact with the sidewall of the contact hole 54 in the region on a lower side than the first region 161 is t, 0.3T≤t≤0.95T may be satisfied, or 0.5T≤t≤0.9T may be satisfied.

FIG. 6B illustrates one example of a manufacturing method of a semiconductor device 100. In the present example, a cross section of the vicinity of the contact hole 54 is shown in a modified example of the flowchart of the manufacturing method shown in FIG. 5.

In FIG. 6B, the manufacturing method without step S108 for etching the first barrier metal layer 61 is shown. In this case, as described above, the film thickness of the first barrier metal layer 61 is formed to be thicker in the vicinity of the stepped portion 39 than in other regions. Therefore, when the second barrier metal layer 62 is formed by sputtering, there is a risk that the second barrier metal layer 62 is not sufficiently formed below the stepped portion 39.

Herein, in step S110, the second barrier metal layer 62 is formed by the CVD method. By forming the second barrier metal layer 62 by the CVD method, the second barrier metal layer 62 can be formed so that it wraps around to the lower side of the thickened first barrier metal layer 61 near the stepped portion 39 and the film thickness of the barrier layer 60 can be formed uniform.

FIG. 6C illustrates one example of a manufacturing method of a semiconductor device 100.

In the present example, a cross section near the contact hole 54 is shown in a further modified example of the flowchart of the manufacturing method shown in FIG. 5.

In FIG. 6C, a manufacturing method without the step S108 for etching the first barrier metal layer 61 is shown. Herein, in the example of FIG. 6C, the film thickness of the first barrier metal layer 61 is different compared to the example of FIG. 6A. Herein, the film thickness of the first barrier metal layer 61 is the film thickness of the first barrier metal layer 61 measured in a direction perpendicular to the tangential direction of the sidewall of the contact hole 54.

The film thickness of the first barrier metal layer 61 formed in step S106′ in FIG. 6C is thinner than the film thickness of the first barrier metal layer 61 formed in step S106 in FIG. 6A. Specifically, the film thickness of the first barrier metal layer 61 formed in step S106 is from 5 nm to 30 nm, while the film thickness of the first barrier metal layer 61 formed in S106′ is from 2.5 nm to 20 nm.

In the example in FIG. 6C, the film thickness of the first barrier metal layer 61 formed in step S106′ is thin, so the film thickness of the first barrier metal layer 61 near the stepped portion 39 is thinner compared to the case of step S106 in FIG. 6A. In this manner, the second barrier metal layer 62 can be formed sufficiently uniformly even if step S108, in which the first barrier metal layer 61 is etched, is omitted.

While the present invention has been described by way of the embodiments, the technical scope of the present invention is not limited to the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, specification, or drawings can be performed in any order as long as the order is not indicated by “prior to,” “before,” or the like and as long as the output from a previous process is not used in a later process. Even if the operation flow is described using phrases such as “first” or “then” in the claims, specification, or drawings, it does not necessarily mean that the process must be performed in this order.

### Explanation of References

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending portion; 32: dummy dielectric film; 33: connecting portion; 34: dummy conductive portion; 38: interlayer dielectric film; 39: stepped portion; 40: gate trench portion; 41: extending portion; 42: gate dielectric film; 43: connecting portion; 44: gate conductive portion; 50: gate metal layer; 52: emitter electrode; 53: front surface side metal layer; 54: contact hole; 55: contact hole; 56: contact hole; 60: barrier layer; 61: first barrier metal layer; 62: second barrier metal layer; 63: silicide layer; 64: plug layer; 65: contact portion; 70: transistor portion; 71: mesa portion; 80: diode portion; 81: mesa portion; 82: cathode region; 85: extension region; 90: boundary portion; 91: mesa portion; 100: semiconductor device; 102: end side; 112: gate pad; 120: active portion; 130: gate runner; 131: inter-active-portion gate runner; 140: edge termination structure portion; 161: first region; 162: second region; 163: third region; 381: first interlayer dielectric film; 382: second interlayer dielectric film.

1. A semiconductor device, comprising:
a semiconductor substrate;
an interlayer dielectric film provided on the semiconductor substrate, having contact holes provided thereon, wherein the contact holes include a contact hole with a stepped portion on a sidewall; and
a contact portion provided in the contact hole,
wherein the contact portion has a barrier layer provided on the sidewall and a bottom surface of the contact hole,
wherein the barrier layer has:
a first region in direct contact with the stepped portion; and
a second region in direct contact with the sidewall of the contact hole in a region lower than the first region, and
wherein when a film thickness of a thickest portion of the first region is T and a film thickness of a thinnest portion of the second region is t, 0.3T≤t≤0.95T is satisfied.

2. The semiconductor device according to claim 1, wherein:
the interlayer dielectric film has:
a first interlayer dielectric film provided to be in direct contact with a front surface of the semiconductor substrate; and
a second interlayer dielectric film provided on the first interlayer dielectric film,
wherein the stepped portion is formed at a boundary between the first interlayer dielectric film and the second interlayer dielectric film.

3. The semiconductor device according to claim 1, wherein the contact portion is a trench contact portion provided to extend from a front surface of the semiconductor substrate toward a depth direction of the semiconductor substrate.

4. The semiconductor device according to claim 1, wherein the barrier layer has:
a first barrier metal layer provided on the sidewall in the contact hole; and
a second barrier metal layer stacked on the first barrier metal layer in the contact hole.

5. The semiconductor device according to claim 4, wherein a film thickness of the second barrier metal layer is thicker than a film thickness of the first barrier metal layer above the stepped portion.

6. The semiconductor device according to claim 4, wherein a film thickness of the second barrier metal layer is thinner than a film thickness of the first barrier metal layer below the stepped portion.

7. The semiconductor device according to claim 1, wherein the film thickness T of the thickest portion of the first region is from 3 nm to 120 nm, and the film thickness t of the thinnest portion of the second region is from 1 nm to 114 nm.

8. The semiconductor device according to claim 4, the film thickness of the first barrier metal layer in the first region is from 2 nm to 119 nm.

9. The semiconductor device according to claim 4, wherein the first barrier metal layer contains either one of Ti, TiN, Ta, or TaN.

10. The semiconductor device according to claim 4, wherein the second barrier metal layer contains either one of TiN or TaN.

11. The semiconductor device according to claim 1, comprising a plug layer provided inside the barrier layer in the contact hole.

12. The semiconductor device according to claim 11, wherein at least one of the barrier layer or the plug layer or both are provided above the interlayer dielectric film.

13. The semiconductor device according to claim 11, wherein the plug layer contains either one of tungsten or molybdenum.

14. The semiconductor device according to claim 1, wherein the sidewall of the contact hole is forward tapered.

15. The semiconductor device according to claim 1, wherein the sidewall of the contact hole is inverted tapered.

16. The semiconductor device according to claim 1, wherein a height of the stepped portion in a direction perpendicular to a tangential direction of the sidewall of the contact hole is 15% or less of an opening width of the contact hole on an upper surface of the interlayer dielectric film.

17. The semiconductor device according to claim 1, wherein:
a film thickness of the barrier layer is:
from 1 nm to 115 nm above the stepped portion; and
from 1 nm to 114 nm below the stepped portion.

18. A manufacturing method of a semiconductor device, comprising:
forming, on a semiconductor substrate, an interlayer dielectric film having contact holes including a contact hole, wherein the contact hole has a stepped portion provided on a sidewall;
providing a barrier layer on the sidewall and a bottom surface of the contact hole; and
providing a plug layer inside the barrier layer in the contact hole,
wherein the barrier layer has:
a first region in direct contact with the stepped portion; and
a second region in direct contact with the sidewall of the contact hole in a region lower than the first region,
wherein when a film thickness of a thickest portion of the first region is T and a film thickness of a thinnest portion of the second region is t, 0.3T≤t≤0.95T is satisfied.

19. The manufacturing method of the semiconductor device according to claim 18, wherein providing the barrier layer has:
providing a first barrier metal layer on the sidewall and the bottom surface in the contact hole; and
providing a second barrier metal layer to be stacked on the first barrier metal layer in the contact hole.

20. The manufacturing method of the semiconductor device according to claim 19, comprising etching the first region after providing the first barrier metal layer and before providing the second barrier metal layer.

21. The manufacturing method of the semiconductor device according to claim 19, wherein a film thickness of the first barrier metal layer in the first region is from 2 nm to 119 nm.

22. The manufacturing method of the semiconductor device according to claim 18, wherein the barrier layer is formed by sputtering.

23. The manufacturing method of the semiconductor device according to claim 18, wherein the plug layer is formed by a CVD method.

24. The manufacturing method of the semiconductor device according to claim 19, wherein the second barrier metal layer is formed by a CVD method.
